(19) United States
(12) Patent Application Publication
(10) Pub. No.: US 2025/0132175 A1
(43) Pub. Date: Apr. 24, 2025

(54) ACTIVELY CONTROLLED WINDOW FOR EPITAXIAL DEPOSITION PROCESS TEMPERATURE CONTROL

(71) Applicant: Applied Materials, Inc., Santa Clara, CA (US)

(72) Inventors: Tetsuya ISHIKAWA, San Jose, CA (US); Kim Ramkumar VELLORE, San Jose, CA (US); Amir H. TAVAKOLI, San Jose, CA (US)

(73) Assignee: Applied Materials, Inc., Santa Clara, CA (US)

(21) Appl. No.: 18/489,214

(22) Filed: Oct. 18, 2023

(51) Int. Cl. H01L 21/67; H01L 21/687

(52) U.S. Cl. CPC H01L 21/67115; H01L 21/68742; H01L 21/68785

(57) ABSTRACT

A window component, a chamber, and a method of processing substrates are described herein. In one example, a semiconductor process chamber window component comprises a transparent quartz body. The body comprises a top surface, a bottom surface, a central portion disposed near a center axis of the body, and one or more fluid channels formed within the body. The one or more fluid channels are configured to flow a fluid from a first side of the body towards a second side of the body and the first side is disposed opposite the second side.

### BACKGROUND

### Field

Embodiments of the present disclosure generally relate to components, chambers, and methods of processing a substrate. More specifically, the embodiments described herein relate to methods of controlling the process temperature of an epitaxial window within a semiconductor processing chamber.

### Description of the Related Art

Semiconductor substrates are processed for a wide variety of applications, including the fabrication of integrated devices and micro-devices. One method of substrate processing includes depositing a material, such as a dielectric material or a conductive metal, on an upper surface of the substrate in a processing chamber. For example, epitaxy is a deposition process that grows a thin, ultra-pure layer, usually of silicon or germanium on a surface of a substrate. The material may be deposited in a lateral flow chamber by flowing a process gas parallel to the surface of a substrate positioned on a support and thermally decomposing the process gas to deposit a material from the process gas onto the substrate surface.

During epitaxial deposition, a process gas is flowed over a substrate and a top surface of a susceptor. The process gas temperature is utilized to form a film or layer on the substrate. There are various ways to control the process gas temperature, including lamps, gas pre-heaters, susceptor heaters, gas supply temperature, and the like. However, conventional heating methods provide localized heating, which may result in variable process gas temperatures between the front end and back end of a substrate during processing. The non-uniformity of the process gas causes non-uniform deposition along the length of the substrate. The non-uniform deposition may be compensated for by rotating the substrate during deposition. Nevertheless, significant amounts of precursor gas are lost, and growth rates at the edges of the substrate are different than growth rates in the center of the substrate.

Therefore, there is a need for improved temperature control of process gases within a processing chamber.

### SUMMARY

A window component, a chamber, and a method of processing substrates are described herein. In one example, a semiconductor process chamber window component comprises a transparent quartz body. The body comprises a top surface, a bottom surface, a central portion disposed near a center axis of the body, and one or more fluid channels formed within the body. The one or more fluid channels are configured to flow a fluid from a first side of the body towards a second side of the body and the first side is disposed opposite the second side.

In another embodiment, a semiconductor process chamber comprises an upper body, a lower body, a pedestal within the process volume, and one or more transmissive windows. The space between the upper body and the lower body define a process volume. Furthermore, each window comprises a circular transparent quartz body. The body comprises a top surface, a bottom surface, a central portion disposed near a center axis of the body, and one or more fluid channels formed within the body. The one or more fluid channels are configured to flow a fluid from a first side of the body towards a second side of the body and the first side is disposed opposite the second side.

In another embodiment, a method of temperature controlling a semiconductor substrate comprises generating thermal energy in an upper volume of a semiconductor chamber, filling a first layer of fluid channels of a transparent quartz body with a first fluid, and conditioning the thermal energy as it passes through the body and into the process volume. The body is disposed between the upper volume and a processing volume and the process volume is configured to support a substrate therein. Furthermore, the body comprises a top surface facing the upper volume, a bottom surface facing the process volume, and the first layer of fluid channels are formed within the body. The first layer of fluid channels are configured to flow a fluid from a first side of the body towards a second side of the body, and wherein the first fluid is an infrared radiation absorbing gas or reflecting gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional side view of a process chamber, according to embodiments of the present disclosure.

FIGS. 2A-2D are a schematic cross-sectional views of a transmissive window of the process chamber of FIG. 1, according to embodiments of the present disclosure.

FIG. 3 is a schematic cross-sectional view of a showerhead, according to one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure is directed towards a temperature-controlled window for controlling the process gas temperature within a semiconductor processing chamber. In various embodiments, the temperature-controlled windows described herein are directed towards use within a deposition chamber, such as an epitaxial deposition chamber. However embodiments of the temperature-controlled windows can be implemented in other chambers, as described below. The temperature-controlled window is configured to enable an increased gas/precursor activation within the processing volume, allowing for improved deposition uniformity on the substrate, reduced operational down time, increased production, and improved cleaning of chamber components.

Temperature variations within a deposition chamber provides challenges, since non-uniform temperature gas profiles result in poor or undesired depositions. Precursors and process gases react with the surface of the substrate to form a film within the processing volume. It is understood that elevated temperatures raise the rates of reactions of the precursor or process gases. Conventionally, these gases are heated as they flow over the substrate with lamps, pre-heat rings, heaters, and the like. These conventional methods to control temperature variations of the precursors and process gases often lead to localized heating or cooling of auxiliary chamber components. The affected temperature of the auxiliary chamber components require time and/or more energy to equalize or achieve the ideal temperature for continued operations. Therefore, efficiently adjusting the temperature of processing volume is desired.

The use of a temperature-controlled window assists in increasing the temperature of the precursors/process gases that are flowed over the substrate. In some embodiments, the temperature-controlled window can also enable even gas distribution to aid in uniform deposition on the substrate. Further, the temperature-controlled window can provide targeted heating zones within the processing volume for tailored heating areas in the processing volume.

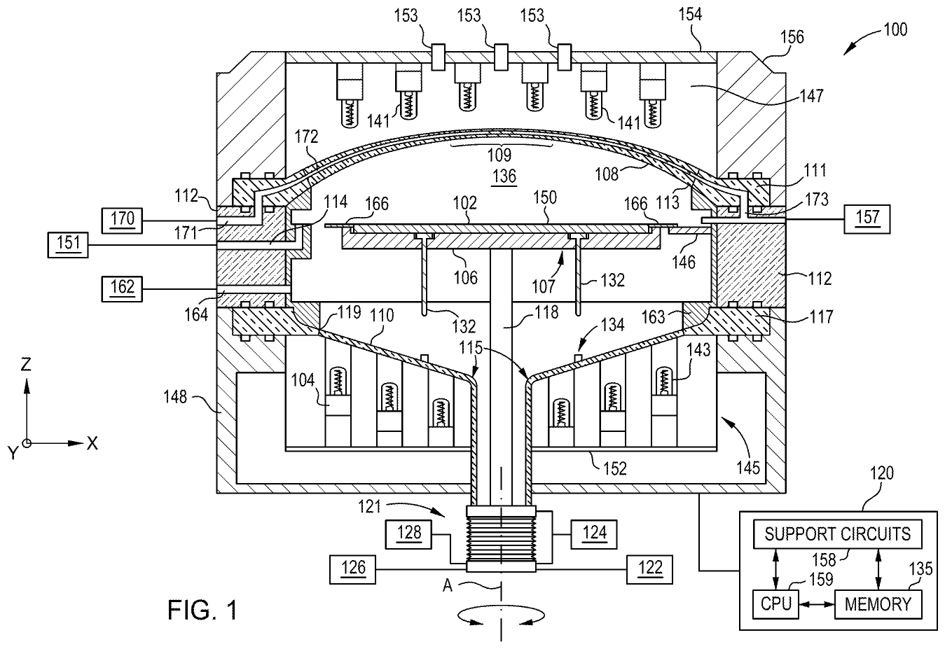

FIG. 1 is a schematic cross-sectional side view of a process chamber 100, such as a deposition chamber, such as an epitaxial deposition chamber with two temperature-controlled windows 108, 110. The process chamber 100 is utilized to grow an epitaxial film on a substrate, such as the substrate 102. The process chamber 100 creates a cross-flow of precursors across the top surface 150 of the substrate 102.

The process chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper transmissive window 108, a lower transmissive window 110, a plurality of upper lamps 141, and a plurality of lower lamps 143. The substrate support 106 is disposed between the upper transmissive window 108 and the lower transmissive window 110. The plurality of upper lamps 141 are disposed between the upper transmissive window 108 and a lid 154. The plurality of upper lamps 141 form an upper lamp assembly 147. The lid 154 includes a plurality of sensors 153 disposed therein for measuring the temperature within the process chamber 100. The plurality of lower lamps 143 are disposed between the lower transmissive window 110 and a floor 152. The plurality of lower lamps 143 form a lower lamp assembly 145.

A process volume 136 is formed between the upper transmissive window 108 and the lower transmissive window 110. In some embodiments, the upper transmissive window 108 may have a dome shape and may be referred to as an upper dome. In other embodiments, the upper transmissive window 108 may be a flat disk. The upper transmissive window 108 has an upper dome portion 109, sometimes referred to as a central window portion, and a support ring 111. The support ring 111 is coupled to an outer edge 113 of the upper transmissive window 108 and is disposed between the upper body 156 and the flow module 112. The lower transmissive window 110 may also have a dome shape. The lower transmissive window 110 has a lower dome portion 115, sometimes referred to as a central window portion in embodiments where the lower dome portion 115 is not dome-shaped. In one or more embodiments, the lower transmissive window 110 has a central opening in the center axis of the lower dome portion 115 for a shaft 118 of the substrate support 106 to be disposed therethrough. In some embodiments, the lower transmissive window 110 may be a flat disk. The lower dome portion 115 of the lower transmissive window 110 is connected to a lower support ring 117 at an outer edge 119 of the lower dome portion 115. The lower support ring 117 is disposed between the lower body 148 and the flow module 112.

The process volume 136 has the substrate support 106 disposed therein. The substrate support 106 includes a top surface on which the substrate 102 is disposed. The substrate support 106 is attached to the shaft 118. The shaft is connected to a motion assembly 121. The motion assembly 121 includes one or more actuators and/or adjustment devices that provide movement and/or adjustment of the shaft 118 and/or the substrate support 106 within the process volume 136. The motion assembly 121 includes a rotary actuator 122 that rotates the shaft 118 and/or the substrate support 106 about a longitudinal axis A of the process chamber 100. The motion assembly 121 further includes a vertical actuator 124 to lift and lower the substrate support 106 in the z-direction. The motion assembly includes a tilt adjustment device 126 that is used to adjust the planar orientation of the substrate support 106 and a lateral adjustment device 128 that is used to adjust the position of the shaft 118 and the substrate support 106 side to side within the process volume 136.

As shown, a controller 120 is in communication with the process chamber 100 and is used to control processes, such as those described herein.

The substrate support 106 may include lift pin holes 107 sized to accommodate a lift pin 132 for lifting of the substrate 102 from the substrate support 106. The lift pins 132 may rest on lift pin stops 134 when the substrate support 106 is lowered from a processing position to a transfer position.

In some embodiments, the flow module 112 includes a plurality of process gas inlets 114, a plurality of purge gas inlets 164, a plurality of temperature regulating fluid inlets 171, and one or more temperature regulating fluid outlets 173 fluidly coupled to the one or more exhaust gas outlets 116. The plurality of process gas inlets 114 and the plurality of purge gas inlets 164 are disposed on the opposite side of the flow module 112 from the one or more exhaust gas outlets 116. One or more flow guides 146 are disposed below the plurality of process gas inlets 114 and the one or more exhaust gas outlets 116. The flow guide 146 is disposed above the purge gas inlets 164. A liner 163 is disposed on the inner surface of the flow module 112 and protects the flow module 112 from reactive gases used during deposition processes. The process gas inlets 114 and the purge gas inlets 164 are positioned to flow a gas over the pre-heat ring 166 and parallel to the top surface 150 of a substrate 102 disposed within the process volume 136. The process gas inlets 114 are fluidly connected to a process gas source 151. The purge gas inlets 164 are fluidly connected to a purge gas source 162. The plurality of temperature regulating fluid inlets 171 are fluidly connected to a temperature regulating fluid source 170. The one or more exhaust gas outlets 116 are fluidly connected to an exhaust pump 157. Each of the process gas source 151 and the purge gas source 162 may be configured to supply one or more precursors or process gases into the process volume 136.

In some embodiments, the plurality of temperature regulating fluid inlets 171, and one or more temperature regulating fluid outlets 173 may be disposed within the upper body 156. In some embodiments, the temperature regulating fluid outlets 173 may be coupled to an independent exhaust system, not shown. Similarly, while not shown, the lower transmissive window 110 may include any combination of the features described herein for the upper transmissive window 108 including, but not limited to, channels within, fluid inlet and outlets, and coupling to an exhaust system.

The following disclosure will discuss various embodiments in reference to the upper transmissive window 108 having a dome shape. It is understood that all the aspects of channel 172 within the upper transmissive window 108 are similarly applicable to the lower transmissive window 110. Aspects of the channel 172 within the transmissive windows 108, 110 are applicable to windows having different shapes, as discussed above. In some embodiments, both the upper transmissive window 108 and the lower transmissive window 110 may possess the same channel structure or design. In some embodiments, the upper transmissive window 108 and the lower transmissive window 110 may have different channel designs to enable targeted thermal transfer in various areas within the process volume 136. Furthermore, aspects of the channel structure may be incorporated into the lower transmissive window 110 without incorporation into the upper transmissive window 108.

The upper transmissive window 108 comprises a plurality of channels 172 embedded within. The channels 172 are coupled to the temperature regulating fluid source 170, the plurality of temperature regulating fluid inlets 171, and one or more temperature regulating fluid outlets 173. The temperature regulating fluid source 170 may comprise various fluid sources to adjust the temperature of the upper transmissive window 108 directly, which indirectly provides temperature control of the gases within the processing volume 136. Contemplated temperature regulating fluids include air, water, and inert gases. In some embodiments, the channels 172 may also flow deposition or cleaning gases. These temperature regulating fluids may be heated or chilled prior to entry into channels 172.

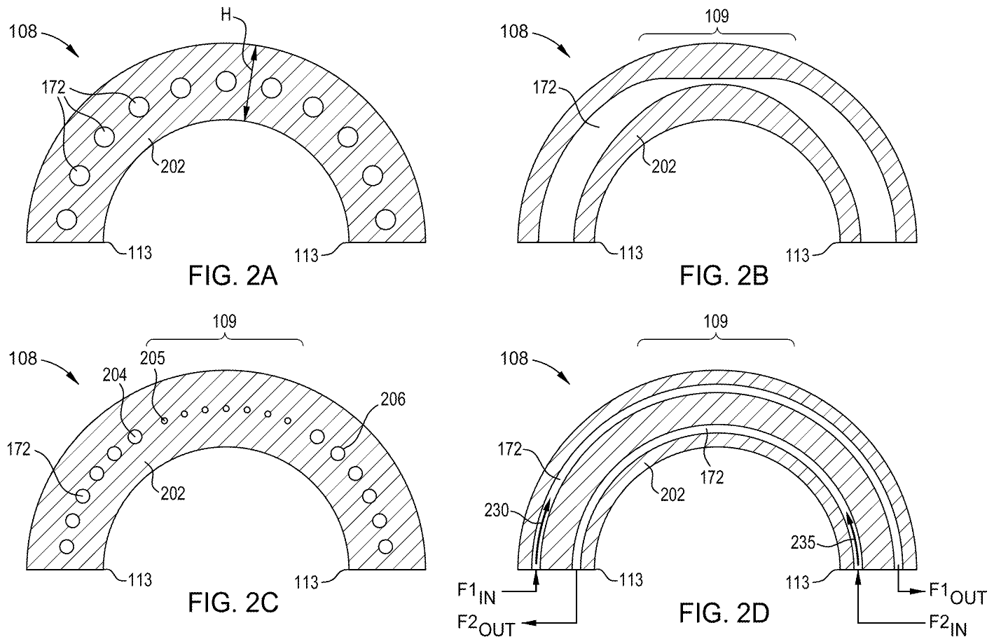

FIG. 2A is a schematic cross-sectional view of the upper transmissive window 108 according to one embodiment. The upper transmissive window 108 may be formed from a quartz or ceramic material. In some embodiments, the quartz material may include several layers of patterned quartz having grooves strategically placed such that, when the layers are diffused together, the patterned quartz layers chemically bond to form a window body 202 with the grooves forming the channels 172. In some embodiments, each individual quartz layer may have a height of about 1 mm to about 5 mm, such as about 1 mm to about 4 mm, such as about 1 mm to about 3 mm, such as about 2 mm. The diffused quartz layers may have a height, H, of about 2 mm to about 30 mm, such as about 6 mm to about 28 mm, such as about 10 mm to about 24 mm, such as about 14 mm to about 22 mm, such as about 18 mm to about 22 mm, such as about 20 mm.

The upper transmissive window 108 may be polished, such as flame polished, allowing for the upper transmissive window 108 to be transparent. In some embodiments, the upper transmissive window 108 is infrared (IR) transparent. IR transparency enables IR energy (i.e., heat) from the upper lamps 141 to penetrate and pass from the upper lamp module 147 to the processing volume 136 of FIG. 1. The channels 172 have a diameter 206 that may be the same size along the cross-section of the upper transmissive window 108. In some embodiments, the diameter 206 may be about 10 micron to about 2000 micron, such as about 20 micron to about 1800 micron, such as about 40 micron to about 1600 micron, such as about 60 micron to about 1400 micron, such as about 80 micron to about 1200 micron, such as about 80 micron to about 1000 micron, such as about 80 micron to about 800 micron, such as about 80 micron to about 600 micron, such as about 80 micron to about 400 micron, such as about 80 micron to about 200 micron, such as about 80 micron to about 100 micron, such as about 20 micron to about 2000 micron, such as about 40 micron to about 2000 micron, such as about 60 micron to about 2000 micron, such as about 80 micron to about 2000 micron, such as about 100 micron to about 2000 micron, such as about 200 micron to about 2000 micron, such as about 400 micron to about 2000 micron, such as about 600 micron to about 2000 micron, such as about 800 micron to about 2000 micron, such as about 1000 micron to about 2000 micron, such as about 1200 micron to about 2000 micron, such as about 1400 micron to about 2000 micron, such as about 1600 micron to about 2000 micron, such as about 1800 micron to about 2000 micron, such as about 100 micron or greater, such as about 80 micron or greater, such as about 60 micron or greater, such as about 40 micron or greater, such as about 20 micron or greater, such as about 10 micron or greater, such as less than about 2000 micron, such as less than about 1800 micron, such as less than about 1600 micron, such as less than about 1400 micron, such as less than about 1200 micron, such as less than about 1000 micron, such as less than about 800 micron, such as less than about 600 micron, such as less than about 400 micron, such as less than about 200 micron, such as less than about 180 micron, such as less than about 160 micron, such as less than about 140 micron, such as less than about 120 micron, such as less than about 100 micron. In some embodiments, such as illustrated in FIG. 2B, the diameter 206 of the channels 172 may vary. Further, the channel 172 has a cross-sectional shape represented as a circle. The cross sectional shape of the channel 172 may be a rectangle, oval, or other shape capable of containing a temperature regulating fluid within.

In some embodiments, a temperature regulating fluid may be flowed through the channels 172. In some embodiments, the channels 172 may be filled with the temperature regulating fluid but not flowed or minimally flowed. For example, certain gases may be selected for specific thermal absorbing properties. One such example, may be a fluid, such as carbon dioxide. Carbon dioxide absorbs IR radiation. The carbon dioxide filled channels 172 may absorb heat from the upper lamps 141 and evenly distribute thermal energy to the spaces between the channels 172 through conduction. In this example, the temperature of the upper transmissive window 108 may be effectively and evenly controlled by the gas properties of the temperature regulating fluid. In similar embodiments, the pressure of the temperature regulating fluid filled channel 172 may be adjusted to control the amount of IR radiation absorbed. In some embodiments, the temperature regulating fluid may be selected for IR reflecting properties. In this example, the fluid may reflect the thermal energy of the upper lamps 141 preventing overheating within the process volume 136. Similarly, pressure of the IR reflecting fluid may be adjusted to enable a custom temperature of the upper transmissive window 108 based on the amount of reflectance the IR reflecting fluid exhibits through a pressure profile.

FIG. 2B is a schematic cross-sectional view of the upper transmissive window 108 that is perpendicular to the cross-sectional view of FIG. 2A according to one embodiment. The channels 172 traverse the span of the window body 202 from each of the outer edge 113. In other words, the channels 172 are configured to flow a fluid from a first side of the upper transmissive window 108 to a second side of the upper transmissive window 108. In some embodiments, the first side and the second side are on opposite sides of the upper transmissive window 108. In some embodiments the channel 172 has a large diameter near the outer edge 113. The channel 172 may have a constant diameter across the window body 202. In some embodiments, as shown, the channel 172 may have a smaller diameter near the upper dome portion 109 that is smaller than the channel 172 diameter near each outer edge 113. Narrowing of the channel 172 diameter allows for a flowing temperature regulating fluid to increase in velocity enabling higher thermal transfer in the areas with narrow fluid path. In some embodiments, the channel 172 diameter may vary along the window body to promote tailored thermal transfer regions. For example, cleaning undesired depositions from the upper transmissive window 108 generally requires heating the window. Having a window body 202 with an embedded channel 172 design that specifically targets the areas prone to undesired depositions, allows the temperature regulating fluid to effectively heat the affect area for better cleaning of the upper transmissive window 108.

FIG. 2C is a schematic cross-sectional view of the upper transmissive window 108 according to one embodiment. As shown, the channels 172 have a large channel diameter 204 and a small channel diameter 205. The larger channel diameter 204 allows for more fluid throughput, enabling a different temperature control impact along the periphery of the upper transmissive window 108 compared to the upper dome portion 109 containing the small channel diameter 205. The small channel diameter 205 allows for accelerated fluid throughput, enabling temperature control along the center of the upper transmissive window 108. In some embodiments, as discussed above, the temperature regulating fluid may flow within the larger channel diameter 204 and not flow, or minimally flow, within the small channel diameter 205. In other embodiments, the temperature regulating fluid may not flow, or minimally flow, within the larger channel diameter 204 and flow within the small channel diameter 205.

Having varying channel diameters enables a tailored temperature regulated zone of the upper transmissive window 108. For example, hot fluid flowing through the channels 172 will have a larger surface area to provide heat transfer within the larger channel diameter 204. In such examples, the hot fluid flowing within the small channel diameter 205 will flow at a faster velocity because of the reduced volume and will exhibit a higher heat transfer within the area of the small channel diameter 205. The difference in diameters enables temperature adjustments in the areas with the small channel diameter 205, thereby producing custom heating or cooling zones. In some embodiments, the size of the large channel diameter 204 and the size of the small channel diameter 205 may be selected independently from about 1000 micron to about 10,000 microns, such as about 1200 micron to about 8000 microns, such as about 1400 micron to about 6000 microns, such as about 1200 micron to about 4,000 microns, such as about 1400 micron to about 2000 microns, such as about 1600 micron to about 1900 microns. In some embodiments, the small channel diameter 205 may be fluidly coupled to the large channel diameters 204 near the outer edge 113. In some embodiments, the small channel diameter 205 may expand to the large channel diameter 204 near the outer edge 113. In some embodiments, the number of the small channel diameter 205 may increase near the upper dome portion 109 to provide more fluid paths and pressure adjusting capabilities as discussed above.

FIG. 2D is a schematic cross-sectional view of the upper transmissive window 108 having multiple layers of channels according to one embodiment. In some embodiments, the window body 202 may have multiple layers of channel 172 pathways. As shown, FIG. 2D has two fluid pathways 230, 235. Each fluid pathway 230, 235 represents an independent fluid path that may be utilized to create a tailored temperature profile of the upper transmissive window 108. The multiple layers of channel 172 pathways enable a crossflow of temperature regulating fluids within an individual layer of channel 172 pathway. The cross flow of fluid may provide a temperature profile along the outer edge 113 that is different than the upper dome portion 109. For example, a hot temperature regulating fluid may provide more thermal energy along the outer edge 113 of the upper transmissive window 108 and a lesser thermal energy near the upper dome portion 109. Thus, the multiple layers of channels enables improved temperature control of the upper transmissive window 108.

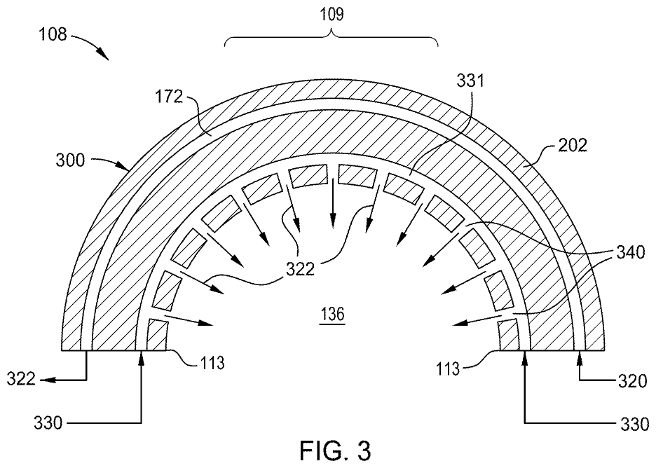

FIG. 3 is a schematic cross-sectional view of the upper transmissive window 108 in a showerhead configuration according to one embodiment. Semiconductor processing chambers, such as the epitaxial deposition chamber shown in FIG. 1, deposit material onto the substrate surface from a side process gas inlet. This side flow of process gas, referred to as a crossflow, flows the process gas across the surface of the substrate. The process gas becomes energized by the thermal energy provided from the upper lamps 141. The energized gas deposits a thin layer of material onto the surface 150 of the substrate 102. However, as mentioned above, the process gas may cause non-uniform deposition along the length of the substrate. The non-uniform deposition may be accounted for through rotation of the substrate. However, uniform deposition is challenging, since temperatures within the process volume 136 may vary leading to, for example, lower deposition growth rates in the center of the substrate. Typical epitaxial deposition chambers were limited to crossflow of process gas, since traditional showerheads impede the IR energy line of sight from the upper lamps 141 to the substrate 102.

FIG. 3 illustrates a showerhead embodiment utilizing the diffused quartz construction of the upper transmissive window 108 similar to FIGS. 2A-2D to provide even distribution of the process gas or inert gas to the process volume 136. In some embodiments, the showerhead 300 has a temperature regulating fluid inlet 320 and outlet 322, multiple process gas inlets 330, and a plurality of process gas outlets 332. All aspects disclosed to the channel 172 of FIGS. 2A-2D are applicable to FIG. 3.

For example, while one temperature regulating fluid channel 172 is illustrated, multiple layers of channels 172 may be implemented within the showerhead 300 to pre-heat the process gas and/or inert before entering the process volume 136. In another example, the diameters of the process gas channel 331 or the temperature regulating fluid channel 172 may be designed to promote targeted heating or cooling zones within the upper transmissive window 108 for improved deposition uniformity. In some embodiments, not shown, an inert gas may flow through the process gas channel 331 to provide a concentration of a crossflowing process gas near the surface 150 of the substrate 102. In some embodiments, not shown, in which the upper transmissive window 108 has a flat shape, the distance to the surface 150 of the substrate 102 may be about 100 microns to about 200,000 microns, such as about 200 microns to about 180,000 microns, such as about 400 microns to about 160,000 microns, such as about 600 microns to about 140,000 microns, such as about 800 microns to about 120,000 microns, such as about 1000 microns to about 100,000 microns, such as about 1200 microns to about 80,000 microns, such as about 1400 microns to about 60,000 microns, such as about 1600 microns to about 40,000 microns, such as about 1800 microns to about 20,000 microns, such as about 2000 microns to about 18,000 microns, such as about 2200 microns to about 16,000 microns, such as about 2400 microns to about 14,000 microns, such as about 2600 microns to about 12,000 microns, such as about 2800 microns to about 10,000 microns, such as about 3000 microns to about 8000 microns, such as about 3200 microns to about 6000 microns, such as about 3400 microns to about 4000 microns, enabling less unused processing volume 136 space that contributes to temperature variations.

In some embodiments, the showerhead 300 has a plurality of apertures 340 that flow process gas and/or inert gas towards the center of the substrate. In other embodiments, the plurality of apertures 340 flow process gas and/or inert gas towards the perimeter of the substrate. In other embodiments, the plurality of apertures process gas and/or inert gas are configured to provide flow to specific areas of the top surface 150 of the substrate 102.

While the foregoing is directed to embodiments of the present disclosure, other and further embodiments of the disclosure may be devised without departing from the basic scope thereof, and the scope thereof is determined by the claims that follow.

What is claimed is:

1. A semiconductor process chamber window component comprising:
a transparent quartz body, the body comprising:
a top surface;
a bottom surface;
a central portion disposed near a center axis of the body;
one or more fluid channels formed within the body, the one or more fluid channels configured to flow a fluid from a first side of the body towards a second side of the body, the first side disposed opposite the second side.

2. The window component of claim 1, wherein the one or more fluid channels are disposed within a first layer of fluid channels, and further comprising a second layer of fluid channels disposed above or below the first layer of fluid channels.

3. The window component of claim 2, wherein the one or more fluid channels are disposed within a first layer of fluid channels, and wherein the first layer of fluid channels is configured to flow a first fluid, and the second layer of fluid channels is configured to flow a second fluid in an opposite direction than the first fluid.

4. The window component of claim 1, wherein the one or more fluid channels are disposed within a first layer of fluid channels, and wherein the one or more fluid channels have a diameter that decreases near the central portion of the body.

5. The window component of claim 1, wherein the one or more fluid channels are disposed within a first layer of fluid channels, and wherein the one or more fluid channels have a first diameter near the first side, a second diameter near the central portion of the body, and a third diameter near the second side, the first diameter and third diameter being greater than the second diameter.

6. The window component of claim 1, wherein the one or more fluid channels are disposed within a first layer of fluid channels, and wherein the one or more fluid channels have a cross-sectional shape comprising a circle, an oval, or a rectangle.

7. The window component of claim 1, wherein the one or more fluid channels are disposed within a first layer of fluid channels, and wherein the body has a height of about 2 mm to about 30 mm.

8. The window component of claim 2, wherein the one or more fluid channels are disposed within a first layer of fluid channels, and wherein the second layer of fluid channels is disposed below the first layer of fluid channels, the second layer of fluid channels having a plurality of apertures fluidly coupled to the bottom surface.

9. The window component of claim 8, wherein the one or more fluid channels are disposed within a first layer of fluid channels, and wherein the plurality of apertures fluidly coupled to the bottom surface are configured to flow into a process volume of a semiconductor chamber.

10. A semiconductor process chamber comprising:
an upper body;
a lower body, a space between the upper body and the lower body defining a process volume;
a pedestal within the process volume; and
one or more transmissive windows, each window comprising:
a circular transparent quartz body, the body comprising:
a top surface;
a bottom surface;
a central portion disposed near a center axis of the body; and
one or more fluid channels formed within the body, the one or more fluid channels configured to flow a fluid from a first side of the body towards a second side of the body, the first side disposed opposite the second side.

11. The window of claim 10, wherein the one or more fluid channels are disposed within a first layer of fluid channels, further comprising a second layer of fluid channels disposed above or below the first layer of fluid channels.

12. The window of claim 11, wherein the one or more fluid channels are disposed within a first layer of fluid channels, and wherein the first layer of fluid channels is configured to flow a first fluid, and the second layer of fluid channels is configured to flow a second fluid in an opposite direction than the first fluid.

13. The window of claim 10, wherein the one or more fluid channels are disposed within a first layer of fluid channels, and wherein the one or more fluid channels have a diameter that decreases near the central portion of the body.

14. The window of claim 10, wherein the one or more fluid channels are disposed within a first layer of fluid channels, and wherein the one or more fluid channels have a first diameter near the first side, a second diameter near the central portion of the body, and a third diameter near the second side, the first and third diameter greater than the second diameter.

15. The window of claim 10, wherein the one or more fluid channels are disposed within a first layer of fluid channels, and wherein one or more fluid channels have a cross sectional shape formed like a circle, an oval, or a rectangle.

16. The window of claim 10, wherein the one or more fluid channels are disposed within a first layer of fluid channels, and wherein the body further comprises a height of about 2 mm to about 30 mm.

17. The window of claim 11, wherein the one or more fluid channels are disposed within a first layer of fluid channels, and wherein the second layer of fluid channels is disposed below the first layer of fluid channels, the second layer or fluid channels having a plurality of apertures fluidly coupled to the bottom surface.

18. The window of claim 17, wherein the one or more fluid channels are disposed within a first layer of fluid channels, and wherein the plurality of apertures fluidly coupled to the bottom surface are configured to flow into the process volume of a semiconductor chamber.

19. A method of temperature controlling a semiconductor substrate comprising:
generating thermal energy in an upper volume of a semiconductor chamber;
filling a first layer of fluid channels of a transparent quartz body with a first fluid, the body disposed between the upper volume and a processing volume, the process volume configured to support a substrate therein, the body comprising:
a top surface facing the upper volume;
a bottom surface facing the process volume; and
the first layer of fluid channels formed within the body, the first layer of fluid channels configured to flow a fluid from a first side of the body towards a second side of the body, wherein the first fluid is an infrared radiation absorbing gas or reflecting gas; and
conditioning the thermal energy as it passes through the body and into the process volume.

20. The method of claim 19, further comprising:
filling a second layer of fluid channels of the transparent quartz body with a second fluid, the second fluid channel formed within the body, the second fluid channel disposed below the first fluid channel, the second fluid channel having a plurality of apertures fluidly coupled to the bottom surface;
wherein a second fluid comprises process gas or an inert gas configured to flow into the process volume, wherein the first fluid conditions the thermal energy and a temperature of the second fluid.
